(19) United States
(12) Patent Application Publication
(10) Pub. No.: US 2025/0259917 A1
(43) Pub. Date: Aug. 14, 2025

(54) POWER MODULE HAVING A MULTI-LEVEL METALLIC FRAME WITH POWER TERMINALS

(71) Applicant: Infineon Technologies AG, Neubiberg (DE)

(72) Inventors: Thomas Schmid, Regensburg (DE); Adrian Lis, Regensburg (DE); Ewald Günther, Regenstauf (DE)

(21) Appl. No.: 18/437,781

(22) Filed: Feb. 9, 2024

(51) Int. Cl. H01L 23/495; H01L 23/00; H01L 23/31; H01L 23/538; H01L 25/07

(52) U.S. Cl. CPC H01L 23/49562; H01L 23/3121; H01L 23/5386; H01L 24/40; H01L 25/072; H01L 2224/40137

(57) ABSTRACT

A power module includes: a substrate having a patterned metallization on an electrically insulative body; a plurality of first power semiconductor dies attached to a first metallic island of the patterned metallization; a plurality of second power semiconductor dies attached to a second metallic island of the patterned metallization; a mold compound at least partly embedding the substrate, the first power semiconductor dies, and the second power semiconductor dies; and a multilevel metallic frame partly embedded in the mold compound and disposed over the substrate. The multilevel metallic frame includes a plurality of power terminals exposed at a side of the mold compound that faces away from the patterned metallization and that transition between two or more different levels to electrically interconnect the first power semiconductor dies and the second power semiconductor dies in a half bridge or full bridge configuration.

### BACKGROUND

Molded power semiconductor modules include power semiconductor dies embedded in a mold compound and electrically interconnected to form a power converter component of a power electronics device, e.g., such as a half bridge or full bridge converter. The signal and power terminals typically jut out from one or more side faces of the mold compound. The power terminals are connected to a busbar and the signal terminals are connected to a printed circuit board (PCB) that has the gate driver and/or controller IC (integrated circuit) used to drive and control the power module. Each power terminal is part of an inductance loop, e.g., such as a DC+ to AC inductance loop, an AC to DC− inductance loop, and a DC+ to DC− inductance loop. Long inductance loops result in high stray inductance, which leads to overvoltage conditions and slower switching frequencies at the power module. Shorter inductance loops are a key challenge in power module design. The power terminal design and signal/power routing on the module substrate are limiting factors. These same factors limit the circuit symmetry achievable by the module design.

Hence, there is a need for power modules and related power electronics assemblies with lower stray inductance.

### SUMMARY

According to an embodiment of a power module, the power module comprises: a substrate comprising a patterned metallization on an electrically insulative body; a plurality of first power semiconductor dies attached to a first metallic island of the patterned metallization; a plurality of second power semiconductor dies attached to a second metallic island of the patterned metallization; a mold compound at least partly embedding the substrate, the first power semiconductor dies, and the second power semiconductor dies; and a multilevel metallic frame partly embedded in the mold compound and disposed over the substrate, wherein the multilevel metallic frame comprises a plurality of power terminals exposed at a side of the mold compound that faces away from the patterned metallization and that transition between two or more different levels to electrically interconnect the first power semiconductor dies and the second power semiconductor dies in a half bridge or full bridge configuration. A power electronic assembly that includes a plurality of the power modules and a busbar attached to the power terminals of the power modules is also described, as are methods of producing the power module.

According to an embodiment of a power electronics assembly for power a multi-phase load, the power electronics assembly comprises: one or more power modules for each phase of the multi-phase load, each power module comprising: a substrate comprising a patterned metallization on an electrically insulative body; a plurality of first power semiconductor dies attached to a first metallic island of the patterned metallization; a plurality of second power semiconductor dies attached to a second metallic island of the patterned metallization; a mold compound at least partly embedding the substrate, the first power semiconductor dies, and the second power semiconductor dies; and a multilevel metallic frame partly embedded in the mold compound and disposed over the substrate, wherein the multilevel metallic frame comprises a plurality of power terminals exposed at a side of the mold compound that faces away from the patterned metallization and that transition between two or more different levels to electrically interconnect the first power semiconductor dies and the second power semiconductor dies in a half bridge or full bridge configuration, wherein the power electronics assembly further comprises a busbar connected to the exposed part of the power terminals of the power modules.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a side perspective view of an embodiment of a power module.

FIG. 1B illustrates a top plan view of the power module.

FIG. 1C illustrates a cross-sectional view of the power module along the line labelled A-A in FIG. 1B.

FIG. 1D illustrates a cross-sectional view of the power module along the line labelled B-B in FIG. 1B.

FIGS. 2A through 2C each illustrate a top plan view (left side of the figures) and a side perspective view (right side of the figures) during different stages of producing the power module shown in FIGS. 1A through 1D.

FIG. 3A illustrates a top plan view of the power module, FIG. 3B illustrates a cross-sectional view of the power module along the line labelled A-A in FIG. 3A, and FIG. 3C illustrates a cross-sectional view of the power module along the line labelled B-B in FIG. 3A, according to another embodiment.

FIG. 4 illustrates a side perspective view of the power module, according to another embodiment.

FIGS. 5A through 5C each illustrate a top plan view (left side of the figures) and a side perspective view (right side of the figures) during different stages of producing the power module shown in FIG. 4.

FIGS. 6 through 9 illustrate a side perspective view of the power module, according to additional embodiments.

FIG. 10 illustrates a partial cross-sectional view of the power module in the region of a single screw type or bolt type power terminal connector.

FIG. 11 illustrates a partial cross-sectional view of the power module in the region of forming a laser welded busbar connection to the exposed part of a power terminal of the power module.

FIG. 12 illustrates a partial cross-sectional view of the power module in the region of forming a laser welded busbar connection to the exposed part of a power terminal of the power module, according to another embodiment.

FIG. 13 illustrates a top plan view of a power electronics assembly, according to an embodiment.

FIG. 14 illustrates a top plan view of the power electronics assembly, according to another embodiment.

### DETAILED DESCRIPTION

The embodiments described herein provide a molded power module design having a low stray inductance, e.g., below 10 nH, below 5 nH, below 3 nH, or even below 2 nH. Such low stray inductance is realized by using a multilevel metallic frame to implement the power terminals of the molded module. The power terminals have a shorter length compared to conventional power module terminals that protrude from one or more side faces of the mold compound. Instead, the power terminals are exposed for connecting to at a side of the mold compound that faces away from the die carrier (substrate) that is at least partly embedded in the mold compound. Such a configuration reduces the length of the power terminals, thus reducing the module stray inductance.

The power terminals transition between two or more different levels to electrically interconnect power semiconductor dies attached to the substrate in a half bridge or full bridge configuration. The multilevel metallic frame may be designed such that power terminals at different potentials have some degree of vertical overlap, further reducing the module stray inductance. The multilevel metallic frame together with a separate metallic frame used for the power module signal connections enable highly symmetric power, gate, and signal routing, which more evenly distributes the current amongst the power semiconductor dies included in the module and reduces deadtime requirements.

Described next, with reference to the figures, are exemplary embodiments of the power module design and corresponding methods of production. Any of the power module embodiments described herein may be used interchangeably unless otherwise expressly stated.

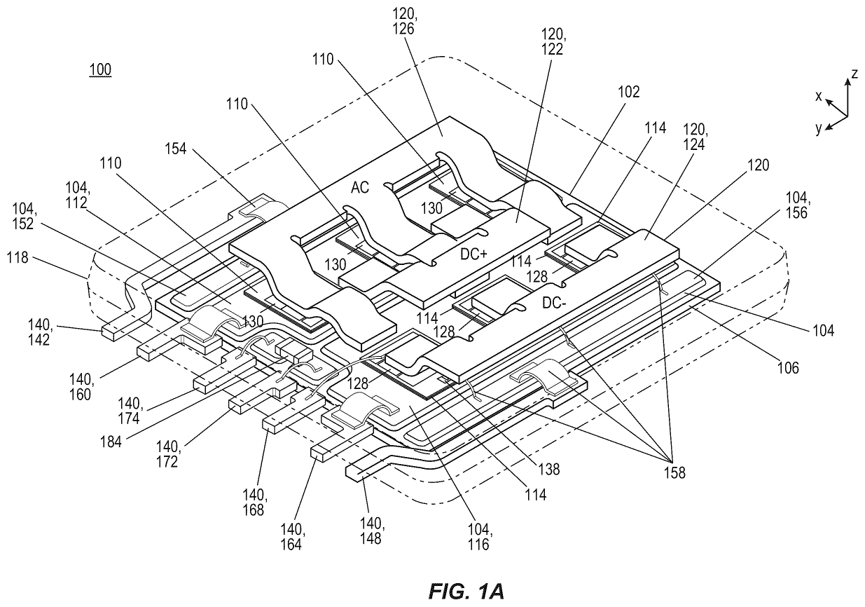

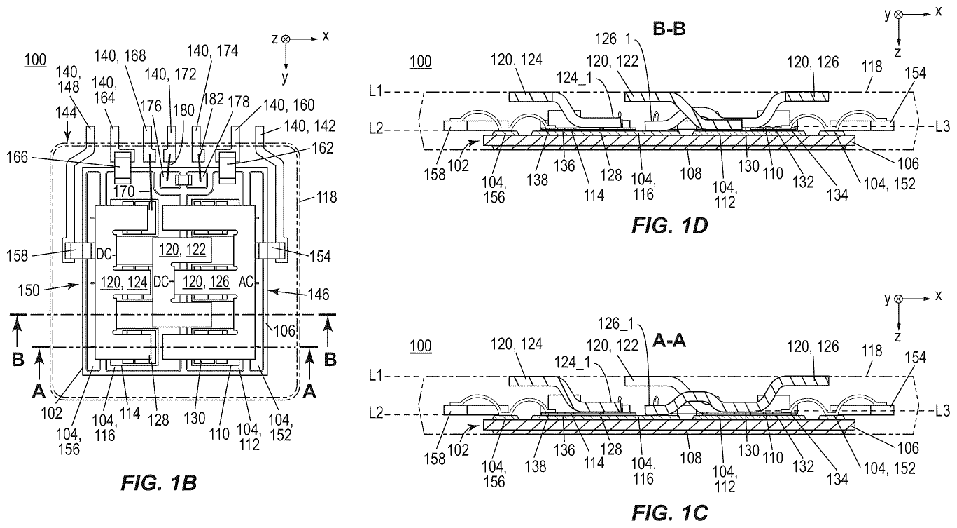

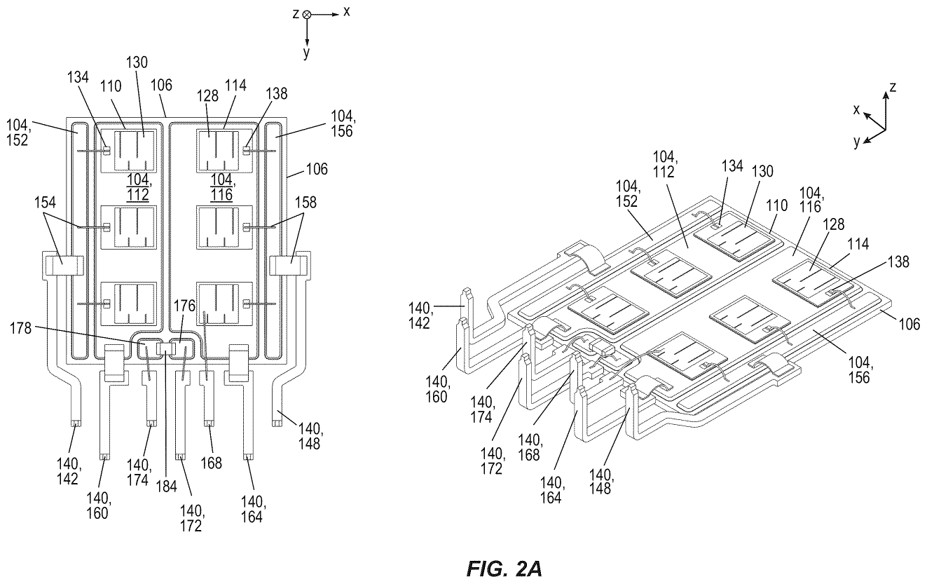

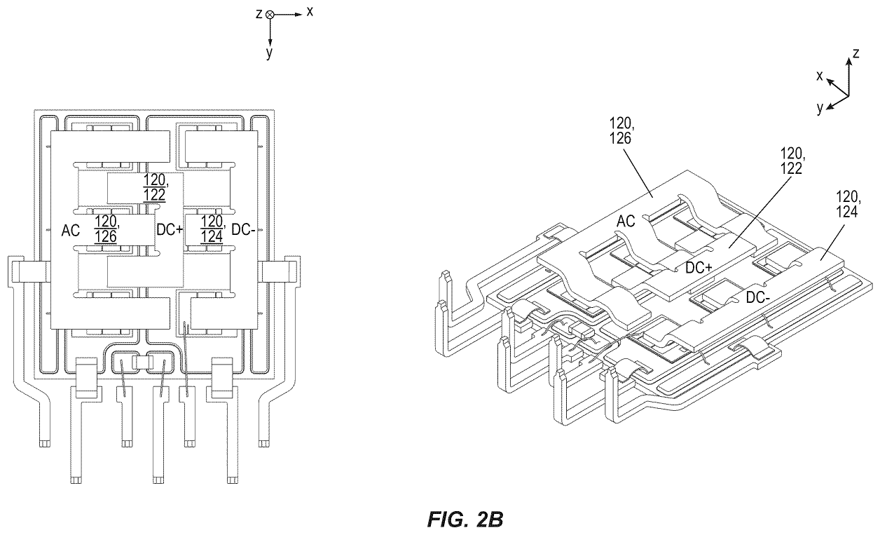

FIG. 1A illustrates a side perspective view of an embodiment of a power module 100. FIG. 1B illustrates a top plan view of the power module 100. FIG. 1C illustrates a cross-sectional view of the power module 100 along the line labelled A-A in FIG. 1B. FIG. 1D illustrates a cross-sectional view of the power module 100 along the line labelled B-B in FIG. 1B. The power module 100 may be part of a power electronics assembly for use in various power applications such as in a DC/AC inverter, a DC/DC converter, an AC/DC converter, a DC/AC converter, an AC/AC converter, a multi-phase inverter, an H-bridge, DC motor drive, etc.

The power module 100 includes a substrate 102 having a patterned first metallization 104 on an electrically insulative body 106. The substrate 102 may also have a second metallization 108 on the opposite side of the electrically insulative body 106 as the patterned first metallization 104. The substrate 102 may be a direct copper bonded (DCB) substrate, an active metal brazed (AMB) substrate, or an insulated metal (IMS) substrate, where in each case the electrically insulative body 106, e.g., a ceramic body, separates the first and second metallizations 104, 108 of the substrate 102 from one another.

The first metallization 104 of the substrate 102 is patterned to ensure proper isolation and signal routing for implementing a power electronics device implemented using the power module 100. Exemplary electrical connections are described in more detail later in the context of a half bridge. However, a half bridge is just one example of a power electronics device that may be implemented using the power module 100. The first metallization 104 of the substrate 102 may be patterned differently than what is illustrated in the figures, to facilitate electrical connections for any type of power electronics device implemented using the power module 100.

The power module 100 also includes first power semiconductor dies 110 attached to a first metallic island 112 of the patterned first metallization 104, and second power semiconductor dies 114 attached to a second metallic island 116 of the patterned first metallization 104. In one embodiment, the power semiconductor dies 110, 114 are vertical power transistor dies. For a vertical power transistor die, the primary current flow path is between the front and back sides of each die 110, 114 (along the z direction in FIGS. 1A through 1D). The drain pad is typically disposed at the die backside, with gate and source pads (and optionally one or more sense pads) at the die frontside. Additional types of semiconductor dies may be included in the power module 100, such as power diode dies, logic dies, controller dies, gate driver dies, etc.

In one embodiment, the power semiconductor dies 110, 114 are SiC power MOSFET (metal-oxide-semiconductor field-effect transistor) dies. The power semiconductor dies 110, 114 instead may be Si power MOSFET dies, HEMT (high-electron mobility transistor) dies, IGBT (insulated-gate bipolar transistor) dies, JFET (junction filed-effect transistor) dies, etc. The first power semiconductor dies 110 may be the same or different type of die as the second power semiconductor dies 114.

A mold compound 118 at least partly embeds the substrate 102, the first power semiconductor dies 110, and the second power semiconductor dies 114. The mold compound 118 is a plastic encapsulant that may be formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound 118 may be formed by injection molding, compression molding, film-assisted molding (FAM), reaction injection molding (RIM), resin transfer molding (RTM), blow molding, etc.

A multilevel metallic frame 120 is partly embedded in the mold compound 118 and disposed over the substrate 102. In FIGS. 1A through 1D, the multilevel metallic frame 120 is disposed above the substrate 102 in the vertical (z) direction. The front (top) surface of the substrate 102 forms a baseline that defines the horizontal plane in FIGS. 1A through 1D. The vertical (z) direction is perpendicular to the horizontal plane, with the horizontal plane being defined by the x and y directions in FIGS. 1A through 1D.

The multilevel metallic frame 120 includes the module power terminals 122, 124, 126 which are exposed at the side of the mold compound 118 that faces away from the patterned first metallization 104 of the substrate 102. The module power terminals 122, 124, 126 transition between two or more different levels L1, L2, L3 to electrically interconnect the first power semiconductor dies 110 and the second power semiconductor dies 114 in a half bridge or full bridge configuration. The multilevel metallic frame 120 may be a multilevel lead frame. The levels, level transitions, and power terminal features of the multilevel metallic frame 120 may be produced by metal processing techniques such as stamping, punching, etching, coining, etc. The multilevel metallic frame 120 may comprise a core metal region with one or more layers or coatings, e.g., adhesion promotion layers, anticorrosion layers, etc.

In the case of a half bridge configuration, the first power semiconductor dies 110 may be electrically coupled in parallel to form a high-side switch device of the half bridge and the second power semiconductor dies 114 may be electrically coupled in parallel to form a low-side switch device of the half bridge. Continuing with the half bridge example, the multilevel metallic frame 120 may provide a high-side (DC+) power terminal 122 for providing a high-side DC current path to the high-side switch device, a low-side (DC−) terminal for providing a low-side DC current path to the low-side switch device, and a phase (AC) terminal 126 for providing a phase or quasi-AC current path to the switch node between the high-side switch device and the low-side switch device. The power terminal configuration of the multilevel metallic frame 120 may be designed for other types of power circuit configurations.

In each case, the power terminals 122, 124, 126 have a shorter length compared to conventional power module terminals that would otherwise protrude from one or more side faces of the mold compound 118 in the x and/or y direction in FIGS. 1A through 1D. Instead, the power terminals are exposed for connecting to at the front (top) side of the mold compound 118 in the z direction in FIGS. 1A through 1D. Such a configuration reduces the length of the power terminals 122, 124, 126, thus reducing the module stray inductance. In one embodiment, the power module 100 has a stray inductance below 10 nH, below 5 nH, below 3 nH, or even below 2 nH by utilizing the multilevel metallic frame 120.

As shown in FIG. 1B, the multilevel metallic frame 120 may be laterally restricted to the footprint of the substrate 102. That is, the multilevel metallic frame 120 may not extend laterally in the x direction or y direction beyond the outer edge or perimeter of the substrate 102. Such a configuration further reduces the length of at least some of the power terminals 122, 124, 126, correspondingly reducing the module stray inductance.

As shown in FIGS. 1C and 1D, the DC+ terminal 122 of the multilevel metallic frame 120 transitions from a first level L1 to a second level L2 in the vertical (z) direction. The DC− terminal 124 of the multilevel metallic frame 120 transitions from the first level L1 to a third level L3 that is between the first level L1 and the second level L2. The phase (AC) terminal 126 of the multilevel metallic frame 120 transitions from the first level L1 to the third level L3 and to the second level L2. At the first level L1, the DC+ terminal 122, the DC− terminal 124, and the phase (AC) terminal 126 are each uncovered by the mold compound and therefore externally accessible at the front (top) side of the mold compound 118 in the z direction.

Further as shown in FIGS. 1C and 1D, at the second level L2, the DC+ terminal 122 of the multilevel metallic frame 120 is attached to the first metallic island 112 of the patterned substrate metallization 104 and the phase (AC) terminal 126 of the multilevel metallic frame 120 is attached to the second metallic island 116 of the patterned substrate metallization 104. At the third level L3, the DC− terminal 124 of the multilevel metallic frame 120 is attached to a load pad 128 of the second power semiconductor dies 114 and the phase (AC) terminal 126 of the multilevel metallic frame 120 is attached to a load pad 130 of the first power semiconductor dies 110.

In one embodiment, the first power semiconductor dies 110 and the second power semiconductor dies 114 are power MOSFET dies. According to this embodiment, a drain pad 132 of each first power semiconductor die 110 is attached to the first metallic island 112 of the patterned substrate metallization 104 at the back side of the first power semiconductor dies 110. The first metallic island 112 of the patterned substrate metallization 104 provides an electrical connection between the drain pad 132 of each first power semiconductor die 110 and the DC+ terminal 122 of the multilevel metallic frame 120. Each first power semiconductor die 110 also has at least a source pad 130 and a gate pad 134 at the front side of the die 110.

Continuing with the power MOSFET example, a drain pad 136 of each second power semiconductor die 114 is attached to the second metallic island 116 of the patterned substrate metallization 104 at the back side of the second power semiconductor dies 114. The second metallic island 116 of the patterned substrate metallization 104 provides an electrical connection between the drain pad 136 of each second power semiconductor die 114 and the phase (AC) terminal 126 of the multilevel metallic frame 120. Each second power semiconductor die 110 also has at least a source pad 128 and a gate pad 138 at the front side of the die 114. At the third level L3, the DC− terminal 124 of the multilevel metallic frame 120 is attached to the source pad 128 of the second power semiconductor dies 114 and the phase (AC) terminal of the multilevel metallic frame 120 is attached to the source pad 130 of the first power semiconductor dies 110. Solder, diffusion solder, glue, adhesive, etc. may be used to make the respective attachments.

The signal connections to the power module 100 may be implemented using an additional metallic frame 140 that is separate and distinct from the multilevel metallic frame 120. In FIGS. 1A through 1D, the additional metallic frame 140 is partly embedded in the mold compound 118 and includes a first gate terminal 142 protruding from a side face 144 of the mold compound 118 and running along a first edge 146 of the substrate 102. The additional metallic frame 140 also includes a second gate terminal 148 protruding from the side face 144 of the mold compound 118 and running along a second edge 150 of the substrate 102 opposite the first edge 146. The gate terminal configuration shown in FIGS. 1A through 1D provides better symmetry of the gate signals provided to the power semiconductor dies 110, 114. The configuration of the patterned substrate metallization 104 shown in FIGS. 1A through 1D similarly provides better power symmetry.

The first gate terminal 142 of the additional metallic frame 140 is electrically connected to a third metallic island 152 of the patterned substrate metallization 104. The third metallic island 152 of the patterned substrate metallization 104 is electrically connected to the gate pad 134 of the first power semiconductor dies 110 by one or more electrical conductors 154 such as a wire ribbon, a metallic clip, bond wires, etc. The second gate terminal 148 of the additional metallic frame 140 is electrically connected to a fourth metallic island 156 of the patterned substrate metallization 104. The fourth metallic island 156 is electrically connected to the gate pad 138 of the second power semiconductor dies 114 by one or more electrical conductors 158 such as a wire ribbon, a metallic clip, bond wires, etc.

In FIGS. 1A through 1D, the third metallic island 152 of the patterned substrate metallization 104 is laterally interposed between the first edge 146 of the substrate 102 and the first metallic island 112 of the patterned substrate metallization 104. The fourth metallic island 156 of the patterned substrate metallization 104 is laterally interposed between the second edge 150 of the substrate 102 and the second metallic island 116 of the patterned substrate metallization 104. According to this embodiment, the first gate terminal 142 and the second gate terminal 148 of the additional metallic frame 140 run lengthwise in a first lateral direction (y direction in FIGS. 1A through 1D) and the part of each power terminal 122, 124, 126 of the multilevel metallic frame 120 exposed at the top (front) side of the mold compound 118 also runs lengthwise in the first lateral direction.

The additional metallic frame 140 may include additional terminals. For example, a first drain sense terminal 160 may be electrically connected to the first metallic island 112 of the patterned substrate metallization 104 by an electrical conductor 162 such as a wire ribbon, a metallic clip, one or more bond wires, etc. A second drain sense terminal 164 may be electrically connected to the second metallic island 116 of the patterned substrate metallization 104 by an electrical conductor 166 such as a wire ribbon, a metallic clip, one or more bond wires, etc. A source sense terminal 168 may be electrically connected to the source pad 128 of the second power semiconductor dies 114 by an electrical conductor 170 such as a wire ribbon, a metallic clip, one or more bond wires, etc. Temperature sense terminals 172, 174 may be electrically connected to fifth and sixth metallic islands 176, 178, respectively, of the patterned substrate metallization 104 by respective electrical conductors 180, 182 such as a wire ribbon, a metallic clip, one or more bond wires, etc. to sense the voltage across a temperature sensor 184 such as an NTC (negative temperature coefficient) thermistor. The power module 100 may include additional terminals, components, etc.

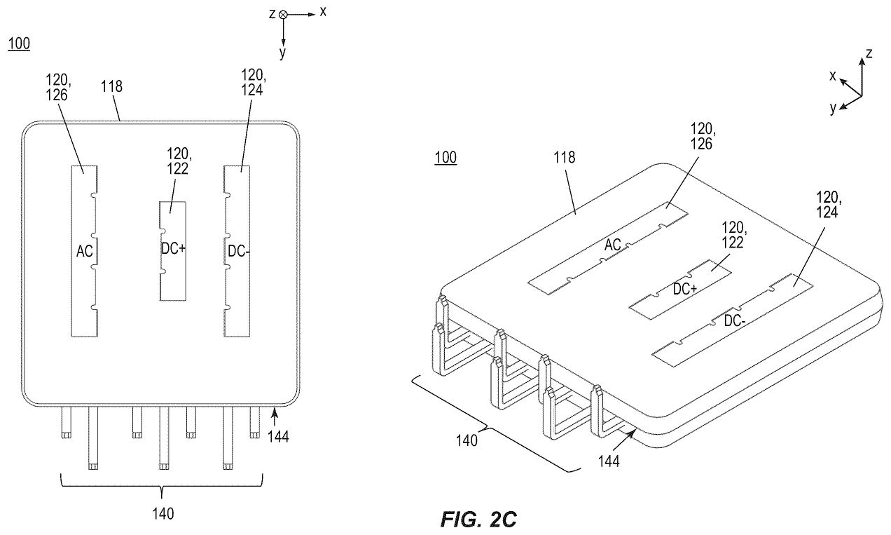

FIGS. 2A through 2C each illustrate a top plan view (left side of the figures) and a side perspective view (right side of the figures) during different stages of producing the power module 100 shown in FIGS. 1A through 1D.

FIG. 2A shows the substrate 102 with the first power semiconductor dies 110 attached to the first metallic island 112 of the patterned substrate metallization 104 and the second power semiconductor dies 114 attached to the second metallic island 116 of the patterned substrate metallization 104. The dies 110, 114 may be attached to the patterned first metallization 104 of the substrate 102 by soldering, diffusion soldering, brazing, welding, gluing, adhering, etc. The terminals 142, 148, 160, 164, 172, 174 of the additional metallic frame 140 may be attached to the patterned first metallization 104 of the substrate 102 during this stage of the module production process.

FIG. 2B shows the power terminals 122, 124, 126 of the multilevel metallic frame 120 attached to the corresponding pads 128, 130 of the respective dies 110, 114 and to the respective metallic islands 112, 116 of the patterned substrate metallization 104. The power terminals 122, 124, 126 of the multilevel metallic frame 120 may be attached by soldering, diffusion soldering, brazing, welding, gluing, adhering, etc.

FIG. 2C shows the power module 100 after the molding process. The mold compound 118 at least partly embeds the substrate 102, the first power semiconductor dies 110, and the second power semiconductor dies 114. The multilevel metallic frame 120 is partly embedded in the mold compound 118 such that the power terminals 122, 124, 126 of the multilevel metallic frame 120 are exposed for contact at the front (top) side of the mold compound 118 in the z direction in FIG. 2C, which reduces the length of the power terminals 122, 124, 126 and thus the module stray inductance. The signal terminals 142, 148, 160, 164, 172, 174 of the additional metallic frame 140 protrude from a side face 144 of the mold compound 118 so that the power terminals 122, 124, 126 and the signal terminals 142, 148, 160, 164, 172, 174 are externally accessible at different sides of the power module 100.

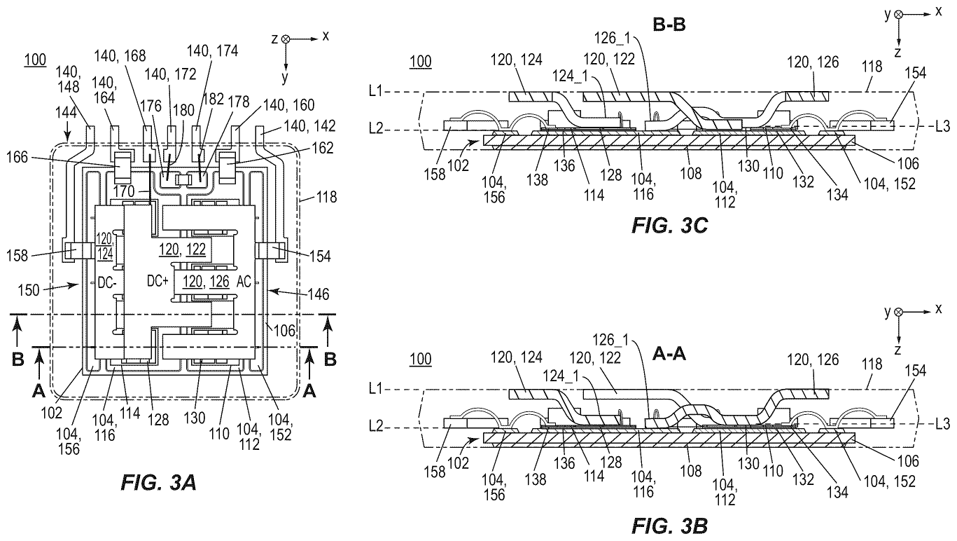

FIG. 3A illustrates a top plan view of the power module 100, FIG. 3B illustrates a cross-sectional view of the power module 100 along the line labelled A-A in FIG. 3A, and FIG. 3C illustrates a cross-sectional view of the power module 100 along the line labelled B-B in FIG. 3A, according to another embodiment. FIGS. 3A, 3B and 3C are the same views as in FIGS. 1B, 1C and 1D, respectively.

In FIGS. 3A, 3B and 3C, the first (DC+) power terminal 122 of the multilevel metallic frame 120 vertically overlaps a part 141_1 of the second (DC−) power terminal 124 of the multilevel metallic frame 120 that is attached to the load pad 128 of the second power semiconductor dies 114. Separately or in combination, the first (DC+) power terminal 122 of the multilevel metallic frame 120 may vertically overlap a part 1261 of the phase (AC) terminal of the multilevel metallic frame 120 that is attached to the second metallic island 116 of the patterned substrate metallization 104. The overlap between the DC+ and DC− terminals 122, 124 and/or the DC+ and AC terminals 122, 126 of the multilevel metallic frame 120 further reduces the module stray inductance since these terminals are at different potentials.

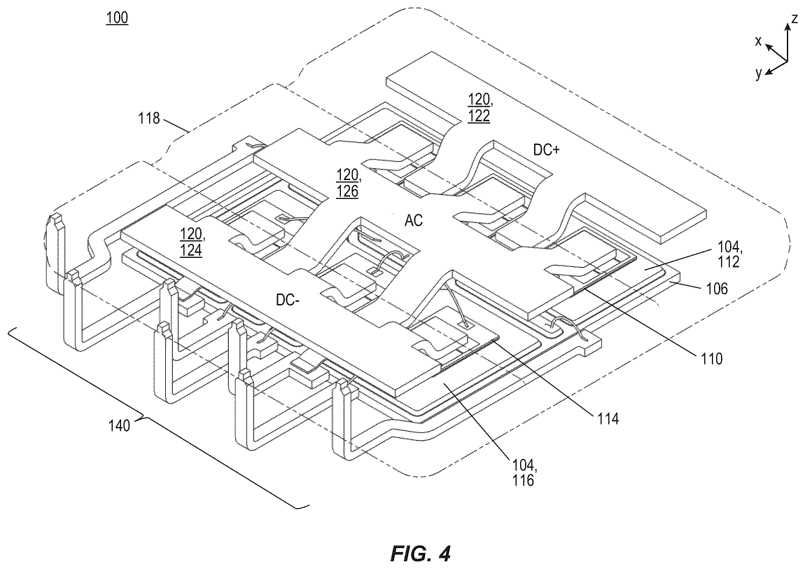

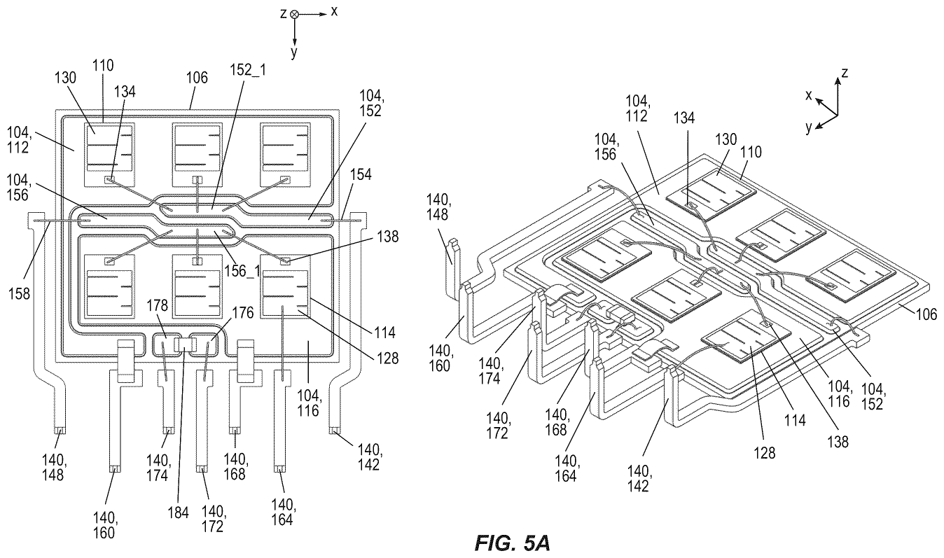

FIG. 4 illustrates a side perspective view of the power module 100, according to another embodiment. FIGS. 5A through 5C each illustrate a top plan view (left side of the figures) and a side perspective view (right side of the figures) during different stages of producing the power module 100 shown in FIG. 4.

FIG. 5A shows the substrate 102 with the first power semiconductor dies 110 attached to the first metallic island 112 of the patterned substrate metallization 104 and the second power semiconductor dies 114 attached to the second metallic island 116 of the patterned substrate metallization 104. The dies 110, 114 may be attached to the patterned first metallization 104 of the substrate 102 by soldering, diffusion soldering, brazing, welding, gluing, adhering, etc. The terminals 142, 148, 160, 164, 172, 174 of the additional metallic frame 140 may be attached to the patterned first metallization 104 of the substrate 102 during this stage of the module production process.

In FIGS. 4 through 5C, the third and fourth metallic islands 152, 156 of the patterned substrate metallization 104 are laterally interposed between the first and second metallic islands 112, 116 of the patterned substrate metallization 104. According to this embodiment, the first and second gate terminals 142, 148 of the additional metallic frame 140 run lengthwise in a first lateral direction (y direction in FIGS. 4 through 5C) and the part of each power terminal 122, 124, 126 of the multilevel metallic frame 120 exposed at the side of the mold compound 118 that faces away from the patterned substrate metallization 104 runs lengthwise in a second lateral direction (x direction in FIGS. 4 through 5C) that is transverse to the first lateral direction.

Also as shown in FIGS. 4 through 5C, an intermediate part 152_1 of the third metallic island 152 of the patterned substrate metallization 104 is laterally interposed between the first metallic island 112 of the patterned substrate metallization 104 and an intermediate part 156_1 of the fourth metallic island 156 of the patterned substrate metallization 104. The intermediate part 156_1 of the fourth metallic island 156 of the patterned substrate metallization 104 is laterally interposed between the second metallic island 116 of the patterned substrate metallization 104 and the intermediate part 152_1 of the third metallic island 152 of the patterned substrate metallization 104.

FIG. 5B shows the power terminals 122, 124, 126 of the multilevel metallic frame 120 attached to the corresponding pads 128, 130 of the respective dies 110, 114 and to the respective metallic islands 112, 116 of the patterned substrate metallization 104. The power terminals 122, 124, 126 of the multilevel metallic frame 120 may be attached by soldering, diffusion soldering, brazing, welding, gluing, adhering, etc.

FIG. 5C shows the power module 100 after the molding process. The mold compound 118 at least partly embeds the substrate 102, the first power semiconductor dies 110, and the second power semiconductor dies 114. The multilevel metallic frame 120 is partly embedded in the mold compound 118 such that the power terminals 122, 124, 126 of the multilevel metallic frame 120 are exposed for contact at the front (top) side of the mold compound 118 in the z direction in FIG. 2C, which reduces the length of the power terminals 122, 124, 126 and thus the module stray inductance. The signal terminals 142, 148, 160, 164, 172, 174 of the additional metallic frame 140 protrude from a side face 144 of the mold compound 118 so that the power terminals 122, 124, 126 and the signal terminals 142, 148, 160, 164, 172, 174 are externally accessible at different sides of the power module 100.

As shown in FIGS. 4 though 5C, the multilevel metallic frame 120 may be laterally restricted to the footprint of the mold compound 118. That is, the multilevel metallic frame 120 may not extend laterally in the x direction or y direction beyond the outer edge or perimeter of the mold compound 118. Such a configuration further reduces the length of at least some of the power terminals 122, 124, 126, correspondingly reducing the module stray inductance.

In FIGS. 1A through 5C, the first DC terminal 122 of the multilevel metallic frame 120 may be interposed between the second DC terminal 124 and the phase terminal 126 of the multilevel metallic frame 120 at the first (exposed) level L1, e.g., as shown in FIGS. 1A through 3C. In another embodiment, the phase terminal 126 of the multilevel metallic frame 120 may be interposed between the first and second DC terminals 122, 124 of the multilevel metallic frame 120 at the first (exposed) level L1, e.g., as shown in FIGS. 4 through 5C. In yet another embodiment, the second DC terminal 124 of the multilevel metallic frame 120 may be interposed between the first DC terminal 122 and the phase terminal 126 of the multilevel metallic frame 120 at the first (exposed) level L1. In each of these embodiments, the exposed part of the power terminals 122, 124, 126 of the multilevel metallic frame 120 may run lengthwise in the y lateral direction (e.g., as shown in FIG. 2C) or the x lateral direction (e.g., as shown in FIG. 5C).

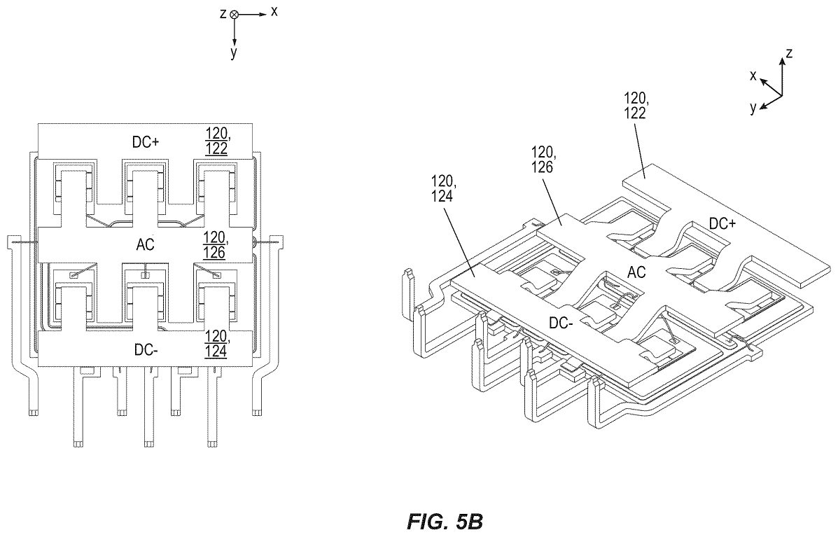

In FIGS. 1A through 5C, the first DC terminal 122, the second DC terminal 124, and the phase terminal 126 of the multilevel metallic frame 120 each run exposed along the side of the mold compound 118 that faces away from the patterned substrate metallization 104. Such a terminal configuration allows for surface mounting of the power module 100 to a busbar. However, the power module 100 may have other power terminal connection configurations for interfacing with a busbar as described next in connection with FIGS. 6 through 9.

FIG. 6 illustrates a side perspective view of the power module, according to an embodiment. In FIG. 6, the first DC terminal 122, the second DC terminal 124, and the phase terminal 126 of the multilevel metallic frame 120 each protrude from the side of the mold compound 119 that faces away from the patterned substrate metallization 104. The protruding part of the power terminals 122, 124, 126 form a tab-like interface for connecting to a busbar.

FIG. 7 illustrates a side perspective view of the power module, according to an embodiment. In FIG. 7, the first DC terminal 122, the second DC terminal 124, and the phase terminal 126 of the multilevel metallic frame 120 form the same tab-like interface as in FIG. 6, but the tabs may have different profiles and optional holes 200 for connecting to a busbar.

FIG. 8 illustrates a side perspective view of the power module, according to an embodiment. In FIG. 8, the first DC terminal 122, the second DC terminal 124, and the phase terminal 126 of the multilevel metallic frame 120 each have an exposed screw type, bolt type, press-fit type, or rivet type connector 202 that protrudes from the side of the mold compound 118 that faces away from the patterned substrate metallization 104. That is, the protruding connector part 202 of the power terminals 122, 124, 126 may have the form of a screw, bolt, press-fit pin, or rivet and provide an interface for connecting to a busbar.

FIG. 9 illustrates a side perspective view of the power module, according to an embodiment. In FIG. 9, the first DC terminal 122, the second DC terminal 124, and the phase terminal 126 of the multilevel metallic frame 120 each have an exposed screw type, bolt type, press-fit type, or rivet type surface connector 204 formed in the exposed part of the terminals 122, 124, 126 at the side of the mold compound 118 that faces away from the patterned substrate metallization 104. That is, the exposed surface connector 204 of the power terminals 122, 124, 126 may have the form of a hole for receiving a screw, bolt, press-fit pin, or rivet and provide an interface for connecting to a busbar.

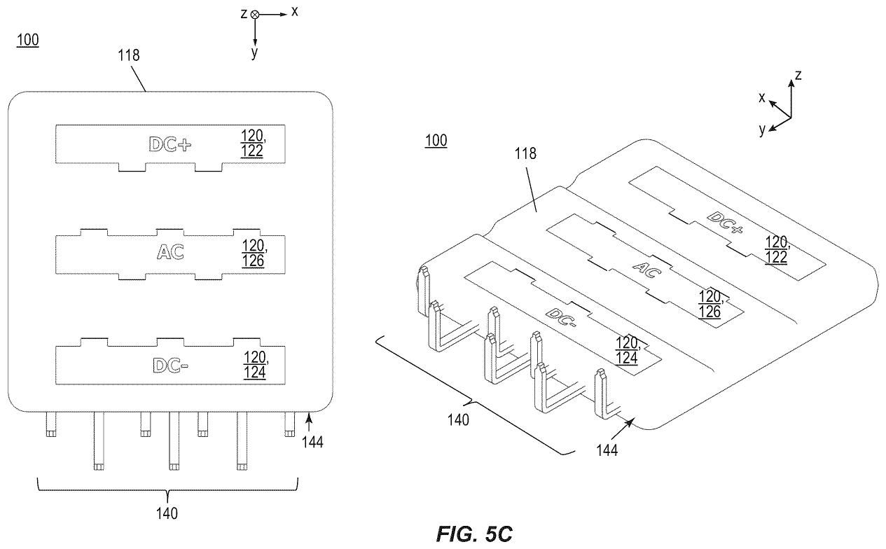

FIG. 10 illustrates a partial cross-sectional view of the power module 100 in the region of a single screw type or bolt type power terminal connector 202 that protrudes from the side of the mold compound 118 that faces away from the patterned substrate metallization 104. The protruding screw type or bolt type power terminal connector 202 has the form of a screw or bolt and provides an interface for connecting to a busbar. The protruding screw type or bolt type power terminal connector 202 may be soldered, welded, brazed, screwed, or riveted to the corresponding power terminal of the multilevel metallic frame 120.

In FIG. 10, the protruding screw type or bolt type power terminal connector 202 is shown with a rivet or press-fit bolt type connection to the second DC terminal 124 of the multilevel metallic frame 120. For example, a rivet connection may be implemented using a rivet nut 204 that is inserted and set entirely from one side of the second DC terminal 124 of the multilevel metallic frame 120. The rivet nut 204 has an internal thread which provides a secure mounting for a threaded bolt 206. Friction drilling instead may be used to make an opening in the second DC terminal 124 of the multilevel metallic frame 120 and thread or press-fit the bolt 206 into the opening. Still other techniques may be used to provide any of the power terminals 122, 124, 126 of the multilevel metallic frame 120 with a screw type, bolt type, press-fit type, or rivet type connector.

The other power terminals 122, 126 of the multilevel metallic frame 120 may also have the screw type or bolt type power terminal connector 202 shown in FIG. 10, or a different type of connector for interfacing with a busbar. More generally, the power terminals 122, 124, 126 of the multilevel metallic frame 120 may use the same or different busbar connector types.

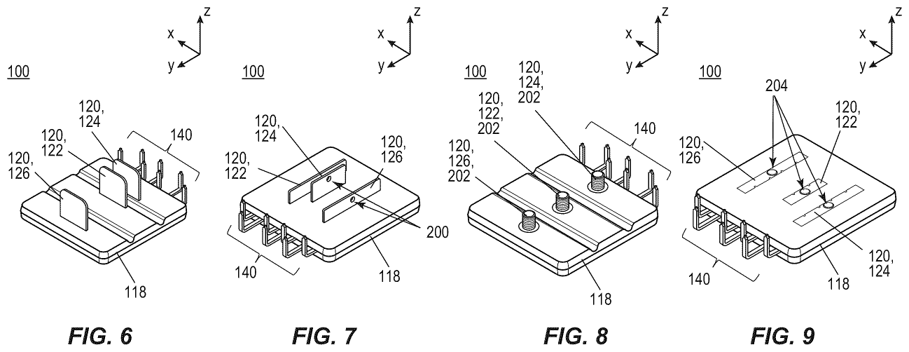

FIG. 11 illustrates a partial cross-sectional view of the power module 100 in the region of forming a laser welded busbar connection to the second power terminal 124 of the multilevel metallic frame 120 at the side of the mold compound 118 that faces away from the patterned substrate metallization 104. The exposed part of the second power terminal 124 is laser welded 300 to a busbar which is not shown in FIG. 11. In one embodiment, the mold compound 118 has an undercut 302 in each region where the power terminals 122, 124, 126 of the multilevel metallic frame 120 are exposed at the side of the mold compound 118 that faces away from the patterned substrate metallization 104. The undercut 302 allows for the laser welding 300 without damaging the mold compound 118.

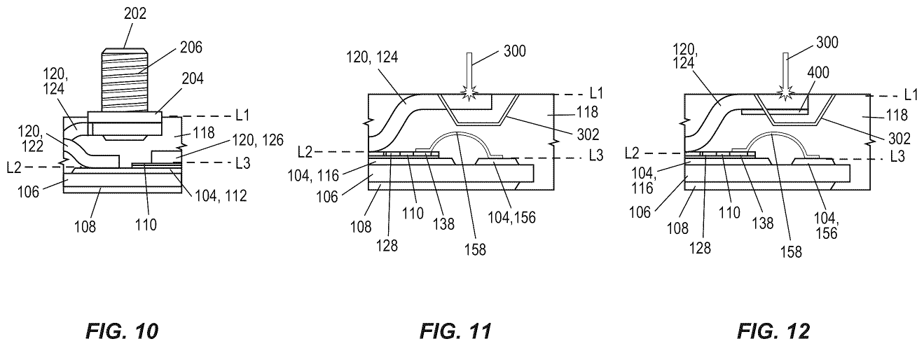

FIG. 12 illustrates a partial cross-sectional view of the power module 100 in the region of forming a laser welded busbar connection to the second power terminal 124 of the multilevel metallic frame 120 at the side of the mold compound 118 that faces away from the patterned substrate metallization 104, according to another embodiment. A heat insulation foil/coating 400 may be provided on the underside of each power terminal 122, 124, 126 of the multilevel metallic frame 120 being laser welded 300, to protect the adjoining mold compound 118 during the laser welding 300. The heat insulation foil/coating 400 may be a standard thermal interface material such as thermal greases, polyimide film, etc. Another non-metallic material with good heat capacity could be attached to the underside to store/buffer heat energy generated during laser welding. The mold compound 118 may or may not have the undercut 302 in each region where the power terminals 122, 124, 126 of the multilevel metallic frame 120 are exposed and laser welded 300 at the side of the mold compound 118 that faces away from the patterned substrate metallization 104.

The power module 100 illustrated in FIGS. 1A through 12 may be included on a power electronics assembly. The power electronics assembly may include a plurality of the power modules 100, e.g., to power two or more phases of a multi-phase load such as a motor drive system. The power modules 100 are connected to a busbar that carries power between the power modules 100 and the load.

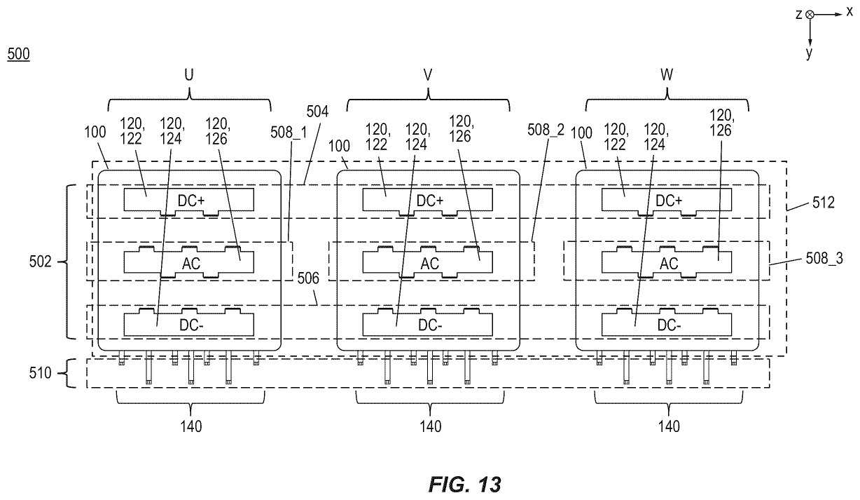

FIG. 13 illustrates a top plan view of a power electronics assembly 500, according to an embodiment. In the example illustrated, the power electronics assembly 500 drives a load (not shown) that has three phases, U, V, W, e.g., such as a motor drive system. In FIG. 13, the power electronics assembly 500 includes a single power module 100 for each phase U, V, W of the load. The exposed part of the power terminals 122, 124, 126 of each power module 100 are connected to a busbar 502. The busbar 502 includes a first metallic strip or bar 504 that provides DC+ potential to the exposed part of the first power terminal 122 of each power module 100. The busbar 502 also includes a second metallic strip or bar 506 that provides DC− potential to the exposed part of the second power terminal 124 of each power module 100. The busbar 502 further includes a separate metallic strip or bar 508_n that forms the respective phase connection (U, V or W) to the exposed part of the phase (AC) terminal 126 of each power module 100, where n corresponds to the individual phases supported by the power electronics assembly 500. The power modules 100 may have any of the connector types previously described herein to facilitate connection to the busbar 502.

The power electronics assembly 500 also includes a control board 110 that has the gate driver and control circuitry for driving and controlling the power semiconductor dies 110, 114 included in the power modules 100. The control board 110 is connected to the terminals of the power modules 100 provided by the additional metallic frame 140 included in the modules 100. The control board 110 may be connected to the terminals of the power modules 100 by soldering, brazing, press-fitting, etc. The metallization 108 at the bottom side of the power modules 100 may be contacted by a heat exchanger 512 such as an actively or passively cooled heat sink, to extract heat dissipated by the power semiconductor dies 110, 114 during operation. The busbar 502, control board 510 and heat exchanger 512 are schematically illustrated in FIG. 13 as dashed rectangles to provide an unobstructed view of the interface between the power modules 100 and the busbar 502, control board 510 and heat exchanger 512.

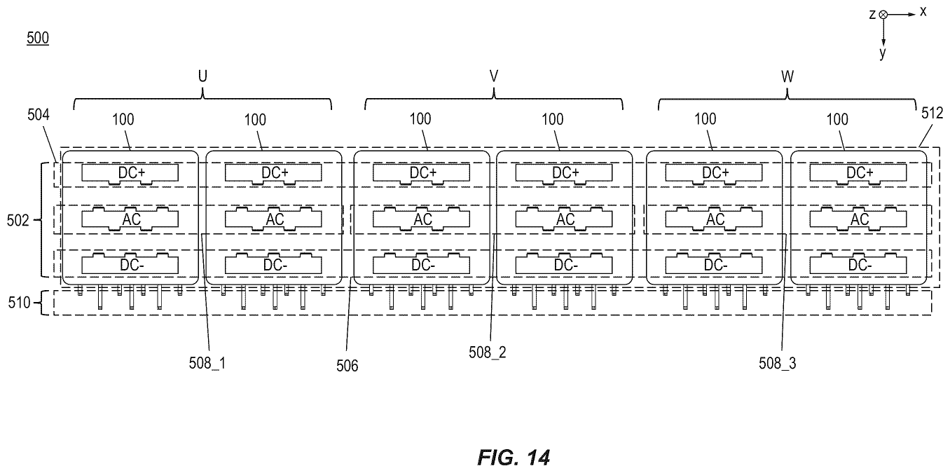

FIG. 14 illustrates a top plan view of the power electronics assembly 500, according to another embodiment. In FIG. 14, the power electronics assembly 500 includes two power modules 100 for each phase U, V, W of the load. More generally, the power electronics assembly 500 may have one or more of the power modules 100 per phase U, V, W, where the number of modules per phase depends on the phase current requirement and the current rating of the power modules 100.

Although the present disclosure is not so limited, the following numbered examples demonstrate one or more aspects of the disclosure.

Example 1. A power module, comprising: a substrate comprising a patterned metallization on an electrically insulative body; a plurality of first power semiconductor dies attached to a first metallic island of the patterned metallization; a plurality of second power semiconductor dies attached to a second metallic island of the patterned metallization; a mold compound at least partly embedding the substrate, the first power semiconductor dies, and the second power semiconductor dies; and a multilevel metallic frame partly embedded in the mold compound and disposed over the substrate, wherein the multilevel metallic frame comprises a plurality of power terminals exposed at a side of the mold compound that faces away from the patterned metallization and that transition between two or more different levels to electrically interconnect the first power semiconductor dies and the second power semiconductor dies in a half bridge or full bridge configuration.

Example 2. The power module of example 1, wherein the power module has a stray inductance below 5 nH.

Example 3. The power module of example 1 or 2, wherein the multilevel metallic frame is laterally restricted to a footprint of the substrate.

Example 4. The power module of any of examples 1 through 3, wherein the plurality of power terminals of the multilevel metallic frame comprises a first DC terminal, a second DC terminal, and a phase terminal.

Example 5. The power module of example 4, wherein the first DC terminal transitions from a first level to a second level, wherein the second DC terminal transitions from the first level to a third level that is between the first level and the second level, wherein the phase terminal transitions from the first level to the third level and to the second level, wherein at the first level, the first DC terminal, the second DC terminal, and the phase terminal are each uncovered by the mold compound.

Example 6. The power module of example 5, wherein at the second level, the first DC terminal is attached to the first metallic island of the patterned metallization and the phase terminal is attached to the second metallic island of the patterned metallization, wherein at the third level, the second DC terminal is attached to a load pad of the second power semiconductor dies and the phase terminal is attached to a load pad of the first power semiconductor dies.

Example 7. The power module of example 6, wherein the first power semiconductor dies are power MOSFET dies each having a drain pad attached to the first metallic island of the patterned metallization at a first side of the first power semiconductor dies and a source pad and a gate pad at a second side opposite the first side, wherein the second power semiconductor dies are power MOSFET dies each having a drain pad attached to the second metallic island of the patterned metallization at a first side of the second power semiconductor dies and a source pad and a gate pad at a second side opposite the first side, wherein at the third level, the second DC terminal is attached to the source pad of the second power semiconductor dies and the phase terminal is attached to the source pad of the first power semiconductor dies.

Example 8. The power module of example 6 or 7, wherein the first DC terminal vertically overlaps a part of the second DC terminal that is attached to the load pad of the second power semiconductor dies.

Example 9. The power module of any of examples 5 through 8, wherein at the first level, the first DC terminal is interposed between the second DC terminal and the phase terminal.

Example 10. The power module of any of examples 5 through 9, wherein at the first level, the second DC terminal is interposed between the first DC terminal and the phase terminal.

Example 11. The power module of any of examples 5 through 10, wherein at the first level, the phase terminal is interposed between the first DC terminal and the second DC terminal.

Example 12. The power module of any of examples 5 through 11, wherein the first metallic island and the second metallic island of the patterned metallization have a lengthwise extension in a first lateral direction, and wherein at the first level, the first DC terminal, the second DC terminal, and the phase terminal each have a lengthwise extension in the first lateral direction.

Example 13. The power module of any of examples 5 through 12, wherein the first DC terminal vertically overlaps a part of the phase terminal that is attached to the second metallic island of the patterned metallization.

Example 14. The power module of any of examples 4 through 13, wherein the first DC terminal, the second DC terminal, and the phase terminal each run exposed along the side of the mold compound that faces away from the patterned metallization.

Example 15. The power module of any of examples 4 through 13, wherein the first DC terminal, the second DC terminal, and the phase terminal each protrude from the side of the mold compound that faces away from the patterned metallization.

Example 16. The power module of examples 4 through 15, wherein the first DC terminal, the second DC terminal, and the phase terminal each have an exposed screw type, bolt type, press-fit type or rivet type connector at the side of the mold compound that faces away from the patterned metallization.

Example 17. The power module of any of examples 4 through 16, wherein the mold compound has an undercut in each region where the first DC terminal, the second DC terminal, and the phase terminal are exposed at the side of the mold compound that faces away from the patterned metallization.

Example 18. The power module of any of examples 1 through 17, further comprising: an additional metallic frame partly embedded in the mold compound and comprising: a first gate terminal protruding from a side face of the mold compound and running along a first edge of the substrate; and a second gate terminal protruding from the side face of the mold compound and running along a second edge of the substrate opposite the first edge, wherein the first gate terminal is electrically connected to a third metallic island of the patterned metallization and the third metallic island is electrically connected to a gate pad of the first power semiconductor dies, wherein the second gate terminal is electrically connected to a fourth metallic island of the patterned metallization and the fourth metallic island is electrically connected to a gate pad of the second power semiconductor dies.

Example 19. The power module of example 18, wherein the third metallic island of the patterned metallization is laterally interposed between the first edge of the substrate and the first metallic island of the patterned metallization, and wherein the fourth metallic island of the patterned metallization is laterally interposed between the second edge of the substrate and the second metallic island of the patterned metallization.

Example 20. The power module of example 18, wherein the third metallic island and the fourth metallic island of the patterned metallization are laterally interposed between the first metallic island and the second metallic island of the patterned metallization.

Example 21. The power module of example 20, wherein an intermediate part of the third metallic island of the patterned metallization is laterally interposed between the first metallic island of the patterned metallization and an intermediate part of the fourth metallic island of the patterned metallization, and wherein the intermediate part of the fourth metallic island of the patterned metallization is laterally interposed between the second metallic island of the patterned metallization and the intermediate part of the third metallic island of the patterned metallization.

Example 22. The power module of any of examples 18 through 21, wherein the first gate terminal and the second gate terminal run lengthwise in a first lateral direction, and wherein the part of each power terminal exposed at the side of the mold compound that faces away from the patterned metallization runs lengthwise in the first lateral direction.

Example 23. The power module of any of examples 18 through 21, wherein the first gate terminal and the second gate terminal run lengthwise in a first lateral direction, and wherein the part of each power terminal exposed at the side of the mold compound that faces away from the patterned metallization runs lengthwise in a second lateral direction that is transverse to the first lateral direction.

Example 24. The power module of any of examples 1 through 23, wherein the multilevel metallic frame is laterally restricted to a footprint of the mold compound.

Example 25. A power electronics assembly for power a multi-phase load, the power electronics assembly comprising: one or more power modules for each phase of the multi-phase load, each power module comprising: a substrate comprising a patterned metallization on an electrically insulative body; a plurality of first power semiconductor dies attached to a first metallic island of the patterned metallization; a plurality of second power semiconductor dies attached to a second metallic island of the patterned metallization; a mold compound at least partly embedding the substrate, the first power semiconductor dies, and the second power semiconductor dies; and a multilevel metallic frame partly embedded in the mold compound and disposed over the substrate, wherein the multilevel metallic frame comprises a plurality of power terminals exposed at a side of the mold compound that faces away from the patterned metallization and that transition between two or more different levels to electrically interconnect the first power semiconductor dies and the second power semiconductor dies in a half bridge or full bridge configuration, wherein the power electronics assembly further comprises a busbar connected to the exposed part of the power terminals of the power modules.

Example 26. The power electronics assembly of example 25, wherein each power module further comprises an additional metallic frame partly embedded in the mold compound and comprising: a first gate terminal protruding from a side face of the mold compound and running along a first edge of the substrate; and a second gate terminal protruding from the side face of the mold compound and running along a second edge of the substrate opposite the first edge, wherein the first gate terminal is electrically connected to a third metallic island of the patterned metallization and the third metallic island is electrically connected to a gate pad of the first power semiconductor dies, wherein the second gate terminal is electrically connected to a fourth metallic island of the patterned metallization and the fourth metallic island is electrically connected to a gate pad of the second power semiconductor dies, wherein the power electronics assembly further comprises a control board that has gate driver and control circuitry for driving and controlling the power semiconductor dies included in the power modules, and wherein the control board is connected to the terminals of the power modules provided by the additional metallic frame included in the power modules.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a substrate comprising a patterned metallization on an electrically insulative body;
a plurality of first power semiconductor dies attached to a first metallic island of the patterned metallization;
a plurality of second power semiconductor dies attached to a second metallic island of the patterned metallization;
a mold compound at least partly embedding the substrate, the first power semiconductor dies, and the second power semiconductor dies; and
a multilevel metallic frame partly embedded in the mold compound and disposed over the substrate,
wherein the multilevel metallic frame comprises a plurality of power terminals exposed at a side of the mold compound that faces away from the patterned metallization and that transition between two or more different levels to electrically interconnect the first power semiconductor dies and the second power semiconductor dies in a half bridge or full bridge configuration.

2. The power module of claim 1, wherein the power module has a stray inductance below 5 nH.

3. The power module of claim 1, wherein the multilevel metallic frame is laterally restricted to a footprint of the substrate.

4. The power module of claim 1, wherein the plurality of power terminals of the multilevel metallic frame comprises a first DC terminal, a second DC terminal, and a phase terminal.

5. The power module of claim 4,
wherein the first DC terminal transitions from a first level to a second level,
wherein the second DC terminal transitions from the first level to a third level that is between the first level and the second level,
wherein the phase terminal transitions from the first level to the third level and to the second level,
wherein at the first level, the first DC terminal, the second DC terminal, and the phase terminal are each uncovered by the mold compound.

6. The power module of claim 5,
wherein at the second level, the first DC terminal is attached to the first metallic island of the patterned metallization and the phase terminal is attached to the second metallic island of the patterned metallization,
wherein at the third level, the second DC terminal is attached to a load pad of the second power semiconductor dies and the phase terminal is attached to a load pad of the first power semiconductor dies.

7. The power module of claim 6,
wherein the first power semiconductor dies are power MOSFET dies each having a drain pad attached to the first metallic island of the patterned metallization at a first side of the first power semiconductor dies and a source pad and a gate pad at a second side opposite the first side,
wherein the second power semiconductor dies are power MOSFET dies each having a drain pad attached to the second metallic island of the patterned metallization at a first side of the second power semiconductor dies and a source pad and a gate pad at a second side opposite the first side,
wherein at the third level, the second DC terminal is attached to the source pad of the second power semiconductor dies and the phase terminal is attached to the source pad of the first power semiconductor dies.

8. The power module of claim 6,
wherein the first DC terminal vertically overlaps a part of the second DC terminal that is attached to the load pad of the second power semiconductor dies.

9. The power module of claim 5,
wherein at the first level, the first DC terminal is interposed between the second DC terminal and the phase terminal.

10. The power module of claim 5,
wherein at the first level, the second DC terminal is interposed between the first DC terminal and the phase terminal.

11. The power module of claim 5,
wherein at the first level, the phase terminal is interposed between the first DC terminal and the second DC terminal.

12. The power module of claim 5,
wherein the first metallic island and the second metallic island of the patterned metallization have a lengthwise extension in a first lateral direction, and
wherein at the first level, the first DC terminal, the second DC terminal, and the phase terminal each have a lengthwise extension in the first lateral direction.

13. The power module of claim 5,
wherein the first DC terminal vertically overlaps a part of the phase terminal that is attached to the second metallic island of the patterned metallization.

14. The power module of claim 4,
wherein the first DC terminal, the second DC terminal, and the phase terminal each run exposed along the side of the mold compound that faces away from the patterned metallization.

15. The power module of claim 4,
wherein the first DC terminal, the second DC terminal, and the phase terminal each protrude from the side of the mold compound that faces away from the patterned metallization.

16. The power module of claim 4,
wherein the first DC terminal, the second DC terminal, and the phase terminal each have an exposed screw type, bolt type, press-fit type or rivet type connector at the side of the mold compound that faces away from the patterned metallization.

17. The power module of claim 4,
wherein the mold compound has an undercut in each region where the first DC terminal, the second DC terminal, and the phase terminal are exposed at the side of the mold compound that faces away from the patterned metallization.

18. The power module of claim 1, further comprising:
an additional metallic frame partly embedded in the mold compound and comprising:
a first gate terminal protruding from a side face of the mold compound and running along a first edge of the substrate; and
a second gate terminal protruding from the side face of the mold compound and running along a second edge of the substrate opposite the first edge,
wherein the first gate terminal is electrically connected to a third metallic island of the patterned metallization and the third metallic island is electrically connected to a gate pad of the first power semiconductor dies,
wherein the second gate terminal is electrically connected to a fourth metallic island of the patterned metallization and the fourth metallic island is electrically connected to a gate pad of the second power semiconductor dies.

19. The power module of claim 18,
wherein the third metallic island of the patterned metallization is laterally interposed between the first edge of the substrate and the first metallic island of the patterned metallization, and
wherein the fourth metallic island of the patterned metallization is laterally interposed between the second edge of the substrate and the second metallic island of the patterned metallization.

20. The power module of claim 18,
wherein the third metallic island and the fourth metallic island of the patterned metallization are laterally interposed between the first metallic island and the second metallic island of the patterned metallization.

21. The power module of claim 20,
wherein an intermediate part of the third metallic island of the patterned metallization is laterally interposed between the first metallic island of the patterned metallization and an intermediate part of the fourth metallic island of the patterned metallization, and
wherein the intermediate part of the fourth metallic island of the patterned metallization is laterally interposed between the second metallic island of the patterned metallization and the intermediate part of the third metallic island of the patterned metallization.

22. The power module of claim 18,
wherein the first gate terminal and the second gate terminal run lengthwise in a first lateral direction, and
wherein the part of each power terminal exposed at the side of the mold compound that faces away from the patterned metallization runs lengthwise in the first lateral direction.

23. The power module of claim 18,
wherein the first gate terminal and the second gate terminal run lengthwise in a first lateral direction, and
wherein the part of each power terminal exposed at the side of the mold compound that faces away from the patterned metallization runs lengthwise in a second lateral direction that is transverse to the first lateral direction.

24. The power module of claim 1, wherein the multilevel metallic frame is laterally restricted to a footprint of the mold compound.
